(19) United States
(12) Patent Application Publication
(10) Pub. No.: US 2014/0020752 A1
(43) Pub. Date: Jan. 23, 2014

(54) PHOTOELECTRIC CONVERTER, AND METHOD FOR PRODUCING SAME

(71) Applicant: SANYO Electric Co., Ltd., Osaka (JP)

(72) Inventors: Mamoru ARIMOTO, Hyogo (JP); Masato SHIGEMATSU, Osaka (JP); Hitoshi SAKATA, Osaka (JP)

(73) Assignee: SANYO Electric Co., Ltd., Osaka (JP)

(21) Appl. No.: 14/032,938

(22) Filed: Sep. 20, 2013

Related U.S. Application Data
(63) Continuation of application No. PCT/JP2012/053841, filed on Feb. 17, 2012.

(30) Foreign Application Priority Data
Mar. 25, 2011 (JP) 2011-068898

(51) Int. Cl. H01L 31/0224; H01L 31/18

(52) U.S. Cl. CPC H01L 31/022441; H01L 31/18
USPC 136/256; 438/96

(57) ABSTRACT

A photoelectric converter (10) is provided with an n-type monocrystalline silicon substrate (21), an IN layer (25) and an IP layer (26) formed on the rear surface (12) of the n-type monocrystalline silicon substrate (21), an n-side electrode (40) electrically connected to the IN layer (25), and a p-side electrode (50) separated from the n-side electrode (40) by means of a separation groove (6) and electrically connected to the IP layer (26). In said photoelectric converter (10), a texture structure is formed on at least a portion of a region in which the n-type monocrystalline silicon substrate (21), the IN layer (25) and the IP layer (26) are formed to be in direct contact with one another.

### CROSS-REFERENCE TO RELATED APPLICATION

The present application is a continuation under 35 U.S.C. §120 of PCT/JP2012/053841, filed Feb. 17, 2012, which is incorporated herein by reference and which claimed priority to Japanese Patent Application No. 2011-068898 filed Mar. 25, 2011. The present application likewise claims priority under 35 U.S.C. §119 to Japanese Patent Application No. 2011-068898 filed Mar. 25, 2011, the entire content of which is also incorporated herein by reference.

### TECHNICAL FIELD

The present invention relates to a photoelectric converter and a method for producing the same.

### BACKGROUND ART

Patent Document 1 discloses a so-called back-contact solar cell in which a p-type semiconductor region with a p-side electrode and an n-type semiconductor region with an n-side electrode are formed on the rear surface side of the solar cell. According to this back-contact solar cell, because no electrode is present on the light receiving surface side, solar light reception efficiency can be increased to thereby enhance power generation efficiency.

### PRIOR ART LITERATURE

### Patent Documents

Patent Document 1: JP 2009-200267 A

### SUMMARY OF THE INVENTION

### Problems to be Solved by the Invention

In a back-contact solar cell, it is important to enlarge the contact area between the semiconductor regions and the electrodes while minimizing variances in electrode widths.

### Means for Solving the Problems

A photoelectric converter according to the present invention comprises a semiconductor substrate, a first amorphous semiconductor layer formed on a first surface of the semiconductor substrate and including a amorphous semiconductor layer of a first conduction type, a second amorphous semiconductor layer formed on the first surface of the semiconductor substrate in a region where the first conduction type amorphous semiconductor layer is absent and including a amorphous semiconductor layer of a second conduction type, a first electrode electrically connected to the first amorphous semiconductor layer, and a second electrode separated from the first electrode by means of a separation groove and electrically connected to the second amorphous semiconductor layer. A textured structure is formed in at least part of a region of the first surface where the first amorphous semiconductor layer and the second amorphous semiconductor layer are formed directly contacting the first surface.

A method for producing a photoelectric converter according to the present invention comprises: a first step of laminating, on a first surface of a semiconductor substrate, a first amorphous semiconductor layer including a amorphous semiconductor layer of a first conduction type; a second step of laminating, on the first surface of the semiconductor substrate in a region where the first conduction type amorphous semiconductor layer is absent, a second amorphous semiconductor layer including a amorphous semiconductor layer of a second conduction type; and a step of forming a first electrode on the first amorphous semiconductor layer and also forming, on the second amorphous semiconductor layer, a second electrode separated from the first electrode by means of a separation groove. The method further comprises a texture forming step of forming a textured structure on the first surface and a second surface of the semiconductor substrate while protecting at least a region of the first surface which eventually receives thereon an electrode edge of the first electrode and an electrode edge of the second electrode that are located along the separation groove.

### Advantages of the Invention

According to the photoelectric converter of the present invention, the contact area between the semiconductor regions and the electrodes can be enlarged while minimizing variances in electrode widths, so that photoelectric conversion efficiency can be further enhanced.

### BRIEF DESCRIPTION OF THE DRAWINGS

FIG. 1 is a plan view, as seen from the rear surface side, of a photoelectric converter according to an embodiment of the present invention.

FIG. 2 is a cross-sectional view taken along line A-A of FIG. 1.

FIG. 3 is a cross-sectional view showing a photoelectric converter according to another embodiment of the present invention.

FIG. 4 is a cross-sectional view for explaining a method for producing a photoelectric converter according to an embodiment of the present invention, the view illustrating a step of producing the photoelectric conversion part.

FIG. 5 is a cross-sectional view for explaining the method for producing the photoelectric converter according to an embodiment of the present invention, the view illustrating the step of producing the photoelectric conversion part.

FIG. 6 is a cross-sectional view for explaining the method for producing the photoelectric converter according to an embodiment of the present invention, the view illustrating the step of producing the photoelectric conversion part.

FIG. 7 is a cross-sectional view for explaining the method for producing the photoelectric converter according to an embodiment of the present invention, the view illustrating the step of producing the photoelectric conversion part.

FIG. 8 is a cross-sectional view for explaining the method for producing the photoelectric converter according to an embodiment of the present invention, the view illustrating the step of producing the photoelectric conversion part.

FIG. 9 is a cross-sectional view for explaining the method for producing the photoelectric converter according to an embodiment of the present invention, the view illustrating the step of producing the photoelectric conversion part.

FIG. 10 is a cross-sectional view for explaining the method for producing the photoelectric converter according to an embodiment of the present invention, the view illustrating a step of forming the n-side electrode and the p-side electrode.

FIG. 11 is a cross-sectional view for explaining the method for producing the photoelectric converter according to an embodiment of the present invention, the view illustrating the step of forming the n-side electrode and the p-side electrode.

FIG. 12 is a cross-sectional view for explaining the method for producing the photoelectric converter according to an embodiment of the present invention, the view illustrating the step of forming the n-side electrode and the p-side electrode.

FIG. 13 is a cross-sectional view for explaining a method for producing a photoelectric converter according to another embodiment of the present invention, the view illustrating a step of producing the photoelectric conversion part.

FIG. 14 is a cross-sectional view for explaining the method for producing the photoelectric converter according to another embodiment of the present invention, the view illustrating the step of producing the photoelectric conversion part.

FIG. 15 is a cross-sectional view for explaining the method for producing the photoelectric converter according to another embodiment of the present invention, the view illustrating the step of producing the photoelectric conversion part.

FIG. 16 is a cross-sectional view for explaining the method for producing the photoelectric converter according to another embodiment of the present invention, the view illustrating the step of producing the photoelectric conversion part.

FIG. 17 is a cross-sectional view for explaining the method for producing the photoelectric converter according to another embodiment of the present invention, the view illustrating the step of producing the photoelectric conversion part.

FIG. 18 is a cross-sectional view for explaining the method for producing the photoelectric converter according to another embodiment of the present invention, the view illustrating the step of producing the photoelectric conversion part.

FIG. 19 is a cross-sectional view for explaining the method for producing the photoelectric converter according to another embodiment of the present invention, the view illustrating the step of producing the photoelectric conversion part.

FIG. 20 is a cross-sectional view for explaining the method for producing the photoelectric converter according to another embodiment of the present invention, the view illustrating the step of producing the photoelectric conversion part.

FIG. 21 is a cross-sectional view for explaining the method for producing the photoelectric converter according to another embodiment of the present invention, the view illustrating the step of producing the photoelectric conversion part.

### EMBODIMENTS OF THE INVENTION

Embodiments of the present invention are described below in detail with reference to the drawings.

The following embodiments are given by way of example only, and the present invention is not limited to those embodiments. Further, the drawings referred to in the description of the embodiments provide schematic views only. For example, dimensional ratios of the articles shown in the drawings may differ from the dimensional ratios of the actual articles. Specific dimensional ratios and the like of the articles should be determined considering the following description.

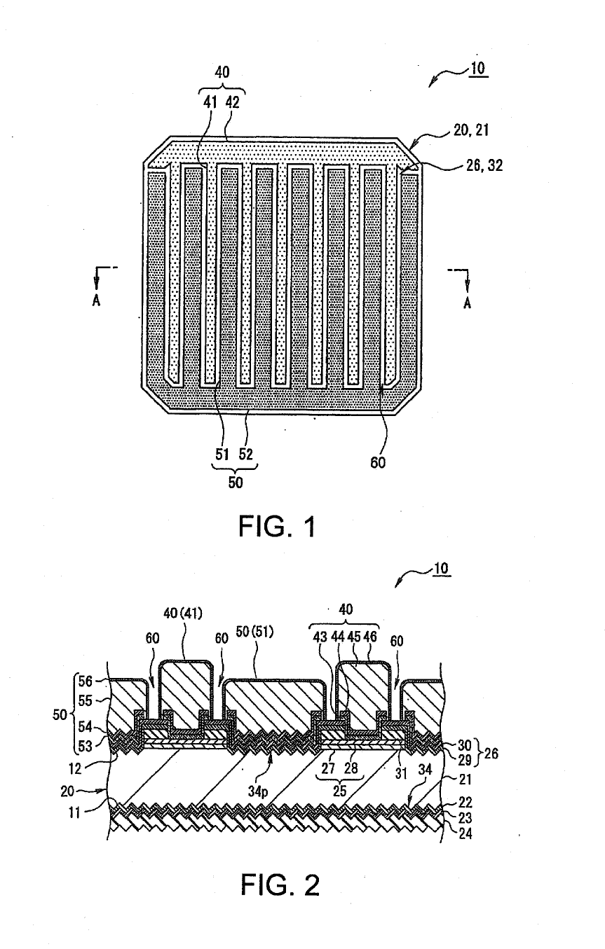

First, configuration of a photoelectric converter 10 will be described in detail with reference to FIGS. 1 and 2.

FIG. 1 is a plan view of the photoelectric converter 10 as seen from the rear surface side.

As shown in FIG. 1, the photoelectric converter 10 comprises a photoelectric conversion part 20 that generates carriers (i.e., electrons and positive holes) upon receiving light such as solar light, and an n-side electrode 40 and a p-side electrode 50 each formed on the rear surface side of the photoelectric conversion part 20. In the photoelectric converter 10, carriers generated in the photoelectric conversion part 20 are collected by the n-side electrode 40 and the p-side electrode 50. Further, by electrically connecting wiring members (not shown) to the n-side electrode 40 and the p-side electrode 50 and thereby modularizing the photoelectric converter 10, the carriers are extracted to the outside as electrical energy. In other words, the photoelectric converter 10 is of a back-contact type having no electrode on the light receiving surface side.

Here, the “rear surface” denotes the surface opposite to the “light receiving surface” which is the surface through which light enters from outside of the device. To state in another way, the surface on which the n-side electrode 40 and the p-side electrode 50 are formed is the rear surface. The n-side electrode 40 is an electrode that collects carriers (i.e., electrons) from an IN amorphous silicon layer 25 of the photoelectric conversion part 20. The p-side electrode 50 is an electrode that collects carriers (i.e., positive holes) from an IP amorphous silicon layer 26 of the photoelectric conversion part 20. Each of these electrodes includes a plurality of finger electrode parts 41, 51 and a bus bar electrode part 42, 52 that connects together the corresponding finger electrode parts.

The photoelectric conversion part 20 comprises an n-type monocrystalline silicon substrate 21, which is a substantially square crystalline semiconductor substrate. While the crystalline semiconductor substrate may alternatively be an n-type polycrystalline silicon substrate or a p-type monocrystalline or polycrystalline silicon substrate, for example, it is preferable to use an n-type monocrystalline silicon substrate 21 as shown in the present embodiment. The n-type monocrystalline silicon substrate 21 functions as a power generation layer, and has a thickness in a range from 100 μm to 300 μm, for example. The n-type monocrystalline silicon substrate 21 has textured structures formed on its light receiving surface 11 and rear surface 12, as will be explained later in detail. Here, the “textured structure” denotes a structure comprising dips and bumps formed in the surfaces of the n-type monocrystalline silicon substrate 21, and is an intentionally created structure. For example, the textured structure is an uneven structure having the function of increasing the amount of light absorption by the photoelectric conversion part 20.

FIG. 2 is a cross-sectional view taken along line A-A of FIG. 1, namely, a cross-sectional view obtained by cutting the finger electrode parts 41, 51 in the width direction.

As shown in FIG. 2, on the light receiving surface 11 side of the n-type monocrystalline silicon substrate 21, it is preferable to sequentially form, for example, an i-type amorphous silicon layer 22, an n-type amorphous silicon layer 23, and a protective layer 24. The i-type amorphous silicon layer 22 and the n-type amorphous silicon layer 23 function as a passivation layer. The protective layer 24 serves to protect the passivation layer and also has the anti-reflection function. For example, the i-type amorphous silicon layer 22 and the n-type amorphous silicon layer 23 are preferably laminated over the entire area of the light receiving surface 11 of the n-type monocrystalline silicon substrate 21 except for the edge region. The i-type amorphous silicon layer 22 is a thin film layer of intrinsic amorphous silicon, and has a thickness in an approximate range from 0.5 nm to 25 nm, for example. The n-type amorphous silicon layer 23 is, for example, a thin film layer of amorphous silicon doped with phosphorus (P) or the like, and has a thickness in an approximate range from 2 nm to 50 nm. The protective layer 24 is preferably laminated over substantially the entire area of the n-type amorphous silicon layer 23. Desirably, the protective layer 24 is composed of a material having a high light-transmitting property. For example, the protective layer 24 is preferably an insulation layer made of silicon oxide (SiO₂), silicon nitride (SiN), silicon oxynitride (SiON), or the like, and is particularly preferably an SiN layer. While the thickness of the protective layer 24 can be changed as appropriate considering the anti-reflection characteristic or the like, the thickness of the protective layer 24 is preferably in an approximate range from 80 nm to 1 μm, for example.

In the photoelectric conversion part 20, on the rear surface side 12 of the n-type monocrystalline silicon substrate 21, there are laminated, for example, an IN amorphous silicon layer 25 (hereinafter referred to as the “IN layer 25”) which is a first amorphous semiconductor layer, an IP amorphous silicon layer 26 (hereinafter referred to as the “IP layer 26”) which is a second amorphous semiconductor layer, and an insulation layer 31. The insulation layer 31 is laminated on a portion of the IN layer 25. The IN layer 25 preferably includes an i-type amorphous silicon layer 27 laminated on the rear surface 12 of the n-type monocrystalline silicon substrate 21, and an n-type amorphous silicon layer 28 laminated on the i-type amorphous silicon layer 27. The i-type amorphous silicon layer 27 is a thin film layer of intrinsic amorphous silicon, and has a thickness in an approximate range from 0.5 nm to 25 nm, for example. The n-type amorphous silicon layer 28 is, for example, a thin film layer of amorphous silicon doped with phosphorus (P) or the like, and has a thickness in an approximate range from 2 nm to 50 nm. The IP layer 26 preferably includes an i-type amorphous silicon layer 29 laminated mainly on the rear surface 12 of the n-type monocrystalline silicon substrate 21, and a p-type amorphous silicon layer 30 laminated on the i-type amorphous silicon layer 29. The i-type amorphous silicon layer 29 is a thin film layer of intrinsic amorphous silicon, and has a thickness in an approximate range from 0.5 nm to 25 nm, for example. The p-type amorphous silicon layer 30 is, for example, a thin film layer of amorphous silicon doped with boron (B) or the like. The thickness of the p-type amorphous silicon layer 30 is in an approximate range from 2 nm to 50 nm, for example. From the perspective of photoelectric conversion efficiency and the like, the IN layer 25 and the IP layer 26 are preferably formed alternately along one direction parallel to the rear surface 12 of the n-type monocrystalline silicon substrate 21. Further, the IN layer 25 and the IP layer 26 are preferably formed over an extensive area on the rear surface 12 of the n-type monocrystalline silicon substrate 21. Accordingly, the IN layer 25 and the IP layer 26 are arranged with a portion of the IN layer 25 and a portion of the IP layer 26 being overlapped on each other, so that one of the layers is overlaid on the other layer and no gaps are present between the two.

FIG. 2 shows an example configuration in which the IP layer 26 is overlaid on the IN layer 25. Hereinafter, the part in which the IN layer 25 and the IP layer 26 are overlapped is described by being referred to as the “overlap part 32”. The width of the overlap part 32 is not particularly limited, but is in an approximate range from 30 μm to 500 μm, for example, and preferably corresponds to approximately ⅓ of the width of the IN layer 25. The width of the IN layer 25 is not particularly limited, but is preferably in an approximate range from 100 μm to 1.5 mm. For example, the width of the IP layer 26 is configured larger than the width of the IN layer 25. Preferably, the area occupied by the IP layer 26 is larger than the area occupied by the IN layer 25.

The insulation layer 31 is formed over the entire area of overlap between the IN layer 25 and the IP layer 26, by being interposed between the IN layer 25 and the IP layer 26. In other words, the insulation layer 31 is preferably formed along the overlap part 32. To state in another way, the IP layer 26 formed over the IN layer 25 is not directly laminated on the IN layer 25 but laminated via the insulation layer 31. Meanwhile, within the region where the IN layer 25 is formed, the insulation layer 31 is absent at portions where the IP layer 26 is not overlaid. According to this configuration, the largest possible contact region can be secured for forming a junction between the IN layer 25 and the n-side electrode 40, while attaining favorable insulation between the IN layer 25 and the IP layer 26.

The n-side electrode 40 is the electrode that is electrically connected to the IN layer 25. The n-side electrode 40 is formed directly contacting mainly the IN layer 25, but is also formed somewhat extending over the overlap part 32. The p-side electrode 50 is the electrode that is electrically connected to the IP layer 26. The p-side electrode 50 is formed directly contacting the IP layer 26, and is also formed somewhat extending over the overlap part 32. Between the n-side electrode 40 and the p-side electrode 50, a separation groove 60 for separating the two electrodes is provided. The separation groove 60 is preferably formed on the overlap part 32. More preferably, the separation groove 60 is formed along the overlap part 32. The width of the separation groove 60 is preferably configured small insofar as sufficient insulation can be provided between the electrodes, and is preferably in an approximate range from 10 μm to 200 μm, for example. Preferably, the n-side electrode 40 and the p-side electrode 50 (i.e., their finger electrode parts and bus bar electrode parts) are each configured as a laminate structure including, for example, a first conductive layer 43, 53, a second conductive layer 44, 54, a third conductive layer 45, 55, and a fourth conductive layer 46, 56. The second to fourth conductive layers are preferably metal layers. For example, by using the second conductive layer 44, 54 as a seed layer that serves as the base for growing a plating, an electroplating method may be performed to form the third conductive layer 45, 55 and the fourth conductive layer 46, 56. On the other hand, the first conductive layer 43, 53 is preferably a transparent conductive layer (i.e., a TCO film). The transparent conductive layer serves to prevent contact between the photoelectric conversion part 20 and the metal layers, and has the function of increasing reflectance by a cooperative effect exerted together with the metal layers. For example, the transparent conductive layer (or TCO film) is preferably formed containing at least one of metal oxides such as indium oxide (In₂O₃), zinc oxide (ZnO), tin oxide (SnO₂), and titanium oxide (TiO₂) having polycrystalline structure. These metal oxides may be doped with a dopant such as tin (Sn), zinc (Zn), tungsten (W), antimony (Sb), titanium (Ti), aluminum (Al), cerium (Ce), and gallium (Ga). For example, ITO obtained by doping In₂O₃ with Sn is particularly preferable. The dopant concentration can be within a range from 0 to 20 wt %. The thickness of the transparent conductive layer is preferably in an approximate range from 50 nm to 100 nm, for example. The second to fourth conductive layers are each preferably composed of metal having high conductivity and high optical reflectance. Examples of metal constituting the respective layers include a metal such as silver (Ag), aluminum (Al), titanium (Ti), copper (Cu), and tin (Sn), or an alloy containing one or more of these metals. For example, the second conductive layer 44, 54 and the third conductive layer 45, 55 are preferably Cu layers, and the fourth conductive layer 46, 56 is preferably an Sn layer. In this case, the Sn layer functions as a protective layer for the Cu layers. The thickness of the Cu layers is preferably in an approximate range from 10 μm to 20 μm, for example. The thickness of the Sn layer is preferably in an approximate range from 1 μm to 5 μm.

Next, the textured structures of the n-type monocrystalline silicon substrate 21 will be described in detail. On the light receiving surface 11 of the n-type monocrystalline silicon substrate 21, the textured structure 34 is preferably formed over substantially the entire area thereof. In contrast, on the rear surface 12 of the n-type monocrystalline silicon substrate 21, the textured structure is formed in at least part of the region where the IN layer 25 and the IP layer 26 are formed directly contacting the rear surface 12. The textured structure is preferably formed under the region where the respective amorphous semiconductor layers and their corresponding electrodes are in direct contact with each other, namely, under the contact regions of the electrodes. The textured structure may be formed in regions where the IN layer 25 and the IP layer 26 are not laminated. Further, the textured structure is preferably not formed in the region which receives thereon an electrode edge of the n-side electrode 40 and an electrode edge of the p-side electrode 50 that are located along the separation groove 60. Also, the textured structure is preferably not formed under the separation groove 60. In the example configuration shown in FIG. 2, within the region where the IP layer 26 is formed, the textured structure 34p is formed over substantially the entire area under the region where the first conductive layer 53 and the IP layer 26 are in direct contact with each other, namely, over substantially the entire area under the contact region of the p-side electrode 50. In other words, within the region where the IP layer 26 is formed, the textured structure 34p is formed over substantially the entire area excluding the region where the insulation layer 31 is formed (i.e., the overlap part 32). As used herein, the expression “substantially the entire area” denotes a state which can be recognized as being essentially the entire area. The expression “over substantially the entire area” denotes a state of covering 95% to 100% of the area. The height of the unevenness of the textured structure is preferably in an approximate range from 1 μm to 30 μm, more preferably in an approximate range from 1 μm to 20 μm, and particularly preferably in an approximate range from 1 μm to 10 μm. Preferably, the width of the textured structure is equivalent to the unevenness height, for example. As the thickness of the amorphous silicon layers is several nm to several ten nm, the textured structure is reflected in the amorphous silicon layers. For example, the textured structure is an uneven structure having pyramid-like shapes (such as rectangular pyramid and rectangular frustum shapes) obtained by performing anisotropic etching on the light receiving surface 11 and the rear surface 12 of the n-type monocrystalline silicon substrate 21 having a (100) plane. The size of the uneven structure can be adjusted by, for example, changing the conditions of the anisotropic etching. In the example configuration shown in FIG. 2, in the region where the IN layer 25 is formed, the textured structure is not formed. The region without the textured structure has a planar surface including no unevenness larger than or equal to several hundred nm. In other words, in the example configuration shown in FIG. 2, the surfaces of the IN layer 25 and the overlap part 32 are planar.

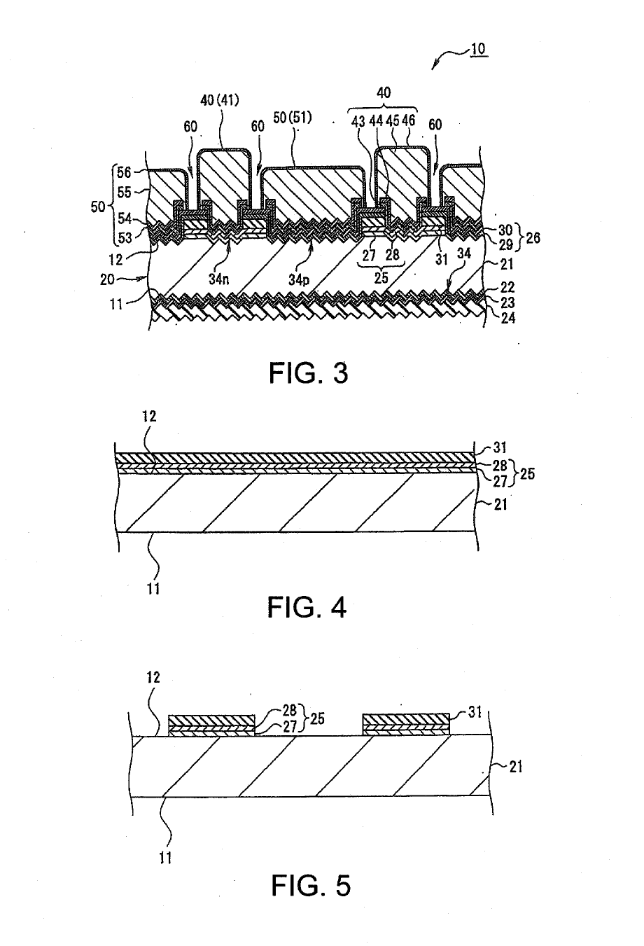

FIG. 3 shows another example of the photoelectric converter 10. In the example configuration shown in FIG. 3, the textured structures 34n, 34p are formed on the rear surface 12 in both of the region where the IN layer 25 is formed and the region where the IP layer 26 is formed. In the region where the IN layer 25 is located, the textured structure 34n is formed in the area under the region where the first conductive layer 43 and the IN layer 25 are in direct contact with each other, namely, in the area under the contact region of the n-side electrode 40. In a corresponding manner, the textured structure 34p is formed in the area under the contact region of the p-side electrode 40. Preferably, the textured structures 34n, 34p are formed over an extensive area excluding the region which receives thereon an electrode edge of the n-side electrode 40 and an electrode edge of the p-side electrode 50 that are located along the separation groove 60. Particularly preferably, the textured structures 34n, 34p are formed over an extensive area excluding the region where the insulation layer 31 is formed (i.e, the overlap part 32).

Next, an example method for producing the photoelectric converter 10 is described with reference to FIGS. 4 to 12. FIGS. 4 to 12 illustrate the process for producing the photoelectric converter 10 shown in FIG. 2.

FIGS. 4 to 9 are diagrams illustrating the steps for producing the photoelectric conversion part 20.

First, as shown in FIG. 4, by means of a method such as plasma-enhanced chemical vapor deposition (PECVD) or sputtering, on a first surface of the n-type monocrystalline silicon substrate 21, the i-type amorphous silicon layer 27, the n-type amorphous silicon layer 28, and the insulation layer 31 are sequentially laminated. In the following description, the first surface corresponds to the “rear surface 12”, and the other surface opposite the rear surface 12 corresponds to the “light receiving surface 11”. In the step of laminating the i-type amorphous silicon film 27 by PECVD, a gas obtained by diluting silane (SiH₄) with hydrogen (H₂) can be used as the raw material gas, for example. Further, in the step of laminating the n-type amorphous silicon film 28, a gas obtained by adding phosphine (PH₃) to silane (SiH₄) and diluting with hydrogen (H₂) can be used as the raw material gas. By changing the hydrogen dilution ratio of the silane gas, the film quality of the i-type amorphous silicon film 27 and the n-type amorphous silicon film 28 can be changed. Furthermore, by changing the mixing concentration of phosphine (PH₃), the doping concentration of the n-type amorphous silicon film 28 can be changed.

Subsequently, as shown in FIG. 5, the respective layers laminated on the rear surface 12 are patterned. First, the insulation layer 31 is partially etched and removed. The region where the insulation layer 31 is removed corresponds to the region of the rear surface 12 where the IP layer 26 is to be laminated in a later step. For example, when etching the insulation layer 31, a resist film formed by a coating process such as screen printing or ink jet, by a photolithographic process, or the like is used as a mask. In cases in which the insulation layer 31 is composed of silicon oxide (SiO₂), silicon nitride (SiN), or silicon oxynitride (SiON), the etching can be performed by means of a hydrogen fluoride (HF) aqueous solution, for example. For example, after completing the etching of the insulation layer 31, the resist film is removed, and then the exposed IN layer 25 is etched using the patterned insulation layer 31 as a mask. The etching of the IN layer 25 is performed by means of an alkali etchant such as a sodium hydroxide (NaOH) aqueous solution (e.g., 1 wt % NaOH aqueous solution), for example. Both of the i-type amorphous silicon layer 27 and n-type amorphous silicon layer 28 constituting the IN layer 25 can be removed by means of the NaOH aqueous solution. As a result of this step, a patterned IN layer 25 and insulation layer 31 are formed on the rear surface 12. For the etching of the IN layer 25, the IP layer 26, and the insulation layer 31, it is also possible to use an etching paste or an etching ink having adjusted viscosity, for example. In such cases, the etching paste is applied by screen printing or ink jet in the region from where the IN layer 25 or the like is to be removed.

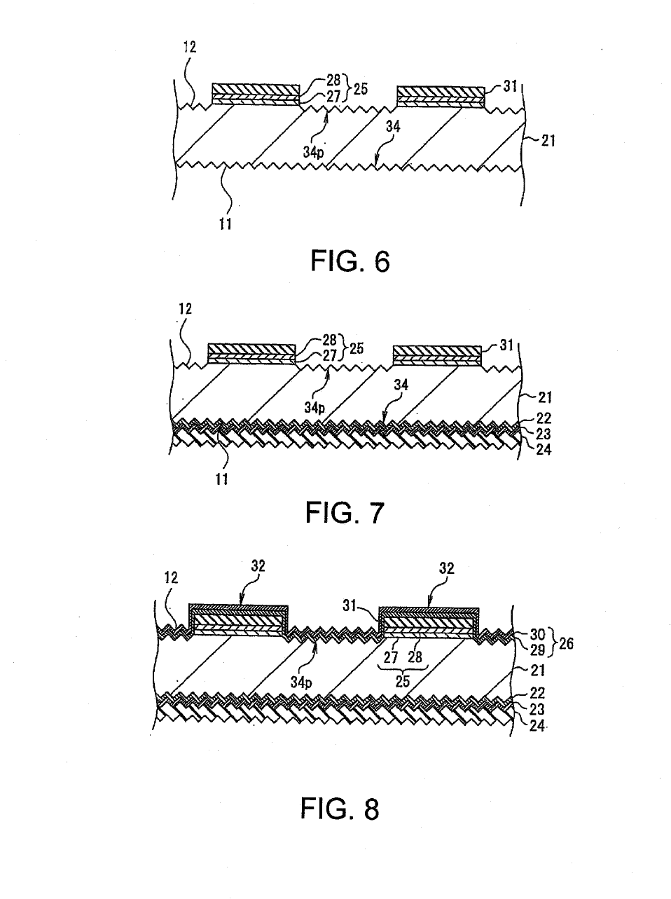

Subsequently, as shown in FIG. 6, the textured structures 34, 34p are formed in the exposed regions of the light receiving surface 11 and rear surface 12, respectively, while using the patterned insulation layer 31 as a mask. On the rear surface 12, the region to be subjected to anisotropic etching corresponds to the region where the IP layer 26 is to be laminated in a later step. Meanwhile, in the region protected by the insulation layer 31, no textured structure is to be formed. In the area above the planar region where no textured structure is formed, the separation groove 60 is to be formed in a later step. The textured structures 34, 34p can be formed by, for example, performing anisotropic etching on the (100) plane of the light receiving surface 11 and rear surface 12 by means of an alkali etchant such as a potassium hydroxide (KOH) aqueous solution (e.g., 1 wt % KOH aqueous solution). In this step, the anisotropic etching is performed on the light receiving surface 11 and the rear surface 12 at the same time, so that the textured structures 34, 34p are formed on the light receiving surface 11 and the rear surface 12, respectively, in one step. In this step, by controlling the etching conditions such as the etchant concentration and the etching time, the unevenness height and the like of the textured structures can be adjusted. Alternatively, formation of the textured structures may be carried out separately for the light receiving surface 11 and the rear surface 12. In this case, for example, the etching conditions can be changed for the light receiving surface 11 and for the rear surface 12, so that textured structures having different unevenness height and the like can be formed on the two surfaces.

Subsequently, as shown in FIG. 7, on the light receiving surface 11, the i-type amorphous silicon layer 22, the n-type amorphous silicon layer 23, and the protective layer 24 are sequentially laminated using a method such as PECVD or sputtering. The unevenness of the textured structure is reflected in each of these layers laminated on the light receiving surface 11.

Subsequently, as shown in FIG. 8, the IP layer 26 is laminated over the rear surface 1562 over the entire area except for the edge region, for example. Specifically, the IP layer 26 is also laminated over the patterned IN layer 25 via the insulation layer 31, thereby forming the overlap part 32 having a planar surface. The IP layer 26 can be formed by performing PECVD, in a manner similar to that for the IN layer 25, to sequentially deposit the i-type amorphous silicon layer 29 and the p-type amorphous silicon layer 30. However, when laminating the p-type amorphous silicon layer 30, diborane (B₂H₆) is used as the raw material gas instead of PH₃. As a result of this step, the region where the textured structure 34p is formed is laminated with the IP layer 26. The unevenness of the textured structure 34p is reflected in the laminated IP layer 26.

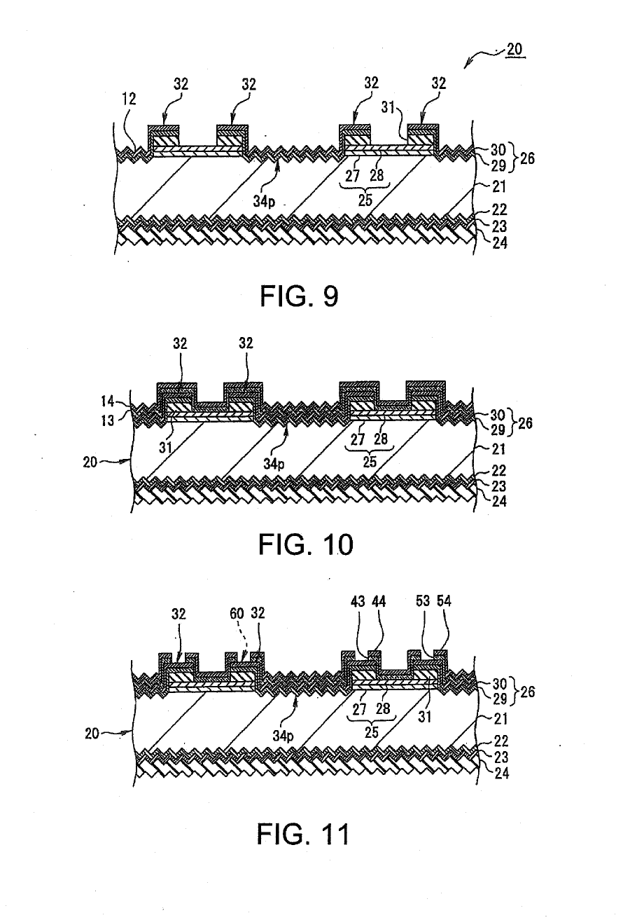

Subsequently, as shown in FIG. 9, the IP layer 26 and insulation layer 31 laminated over the IN layer 25 are partially etched and removed. In this step, for example, a resist film formed by screen printing or the like is used as a mask to etch the IP layer 26, and this patterned IP layer 26 is used as a mask to etch the insulation layer 31. As a result of this step, part of the IN layer 25 becomes exposed. Because the IP layer 26 is more resistant to etching compared to the IN layer 25, it is preferable to use an NaOH aqueous solution having a higher concentration that that for etching the IN layer 25 (for example, 10 wt % NaOH aqueous solution), or fluoro-nitric acid (HF, HNO₃) (for example, 30 wt % each of HF and HNO₃). Alternatively, use of the NaOH aqueous solution by heating it to a temperature in an approximate range from 70 to 90° C. (i.e., thermal alkali treatment) is also preferable.

FIGS. 10-12 are diagrams illustrating the process for forming the n-side electrode 40 and the p-side electrode 50.

The following description refers to an example process in which the second conductive layer 44, 54 of each electrode is used as the seed layer to form, by means of electroplating, the third conductive layer 45, 55 and fourth conductive layer 46, 56 of the corresponding electrode.

First, for example, as shown in FIG. 10, the first conductive layer 13 and the second conductive layer 14 are sequentially formed over the IN layer 25 and the IP layer 26 by sputtering or the like. For example, the first conductive layer 13 and the second conductive layer 14 are laminated in substantially the entire area over the IN layer 25 and the IP layer 26. Here, the first conductive layer 13 is the layer which will be patterned in a later step so as to form the first conductive layers 43, 53 for the respective electrodes. The second conductive layer 14 is the layer which will be patterned in a later step so as to form the second conductive layers 44, 54 for the respective electrodes. The first conductive layer 13 and the second conductive layer 14 are each formed to have a thickness in an approximate range from several ten nm to several hundred nm. Accordingly, the unevenness of the textured structure 34p is reflected in the first conductive layer 13 and the second conductive layer 14. Meanwhile, the surfaces of the first conductive layer 13 and second conductive layer 14 which are formed over the IN layer 25 and the overlap part 32 are planar.

Subsequently, as shown in FIG. 11, the first conductive layer 13 and the second conductive layer 14 are partially etched to divide each of these layers, thereby forming separate first conductive layers 43, 53 and separate second conductive layers 44, 45 for the respective electrodes. The etched region is the region over the planar overlap part 32, and this etching position determines the position where the separation groove 60 is to be formed. In other words, the separation groove 60 is formed above the overlap part 32. For example, the etching of the first conductive layer 13 and the second conductive layer 14 is performed by means of an aqueous solution containing ferric chloride (FeCl₃) and hydrochloric acid (HCl), while using a resist film formed by screen printing or the like as a mask.

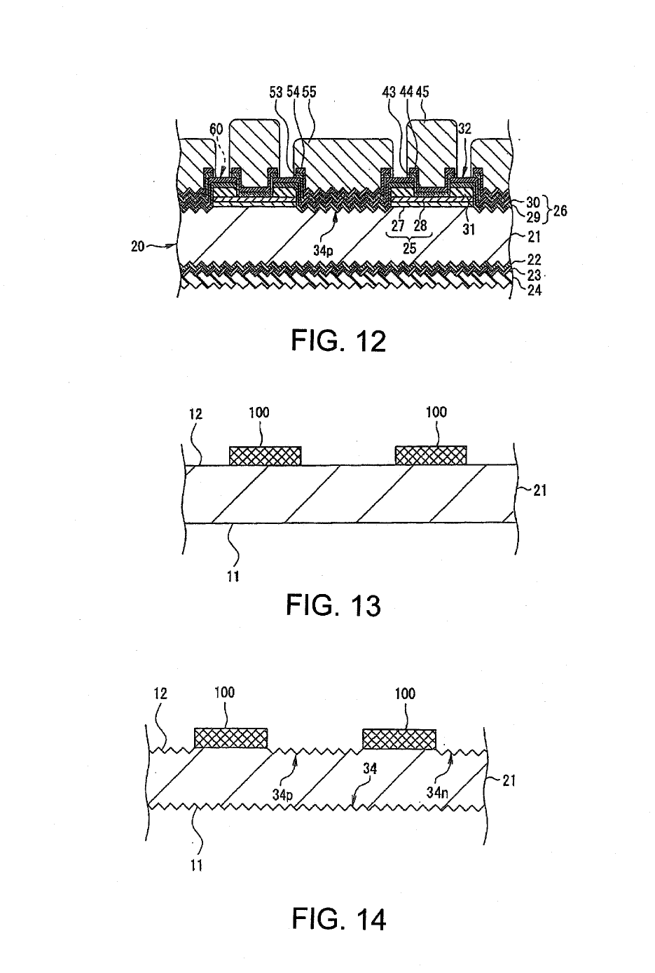

Subsequently, as shown in FIG. 12, by using the second conductive layers 44, 45 as the seed layer, the third conductive layers 45, 55 are respectively formed by electroplating. Further, by forming the fourth conductive layers 46, 56 on the third conductive layers 45, 55 by electroplating, the photoelectric converter 10 (see FIG. 2) having the n-side electrode 40 and the p-side electrode 50 on the rear surface side of the photoelectric conversion part 20 can be obtained. For example, the electroplating can be carried out by causing an electric current having the same magnitude to flow through the second conductive layer 44 constituting the n-side electrode 40 and through the second conductive layer 54 constituting the p-side electrode 50. In this case, metal plating layers having the same mass are formed on the respective second conductive layers 44, 54. Accordingly, in the n-side electrode 40 having a smaller lamination area compared to the p-side electrode 50, the thickness of the third conductive layer becomes larger. In other words, by performing the electroplating by causing a current having the same magnitude to flow, the thickness of the n-side electrode 40 can be made larger than the thickness of the p-side electrode 50.

Next, a method for producing the photoelectric converter 10 shown in FIG. 3 is described with reference to FIGS. 13 to 21. In the following, description of the steps that are identical to the steps of the above-described production method will not be repeated.

First, as shown in FIG. 13, a resist film 100 is formed on a first surface of the n-type monocrystalline silicon substrate 21 by screen printing or the like, for example. In this step, instead of the resist film 100, a protective layer that would not be etched in the texture formation step, such as an SiN layer, may alternatively be formed as a mask. In the following description, the first surface corresponds to the “rear surface 12”, and the other surface opposite the rear surface 12 corresponds to the “light receiving surface 11”.

Subsequently, as shown in FIG. 14, the resist film 100 is used as a mask to perform anisotropic etching on the exposed regions of the light receiving surface 11 and the rear surface 12, thereby forming the textured structures 34, 34n, 34p. On the rear surface 12, the region subjected to the anisotropic etching corresponds to the region where the IN layer 25 and the IP layer 26 are to be laminated in a later step. Meanwhile, in the region protected by the resist film 100, no textured structure is formed. In the area above the planar region where no textured structure is formed, the separation groove 60 will be formed in a later step.

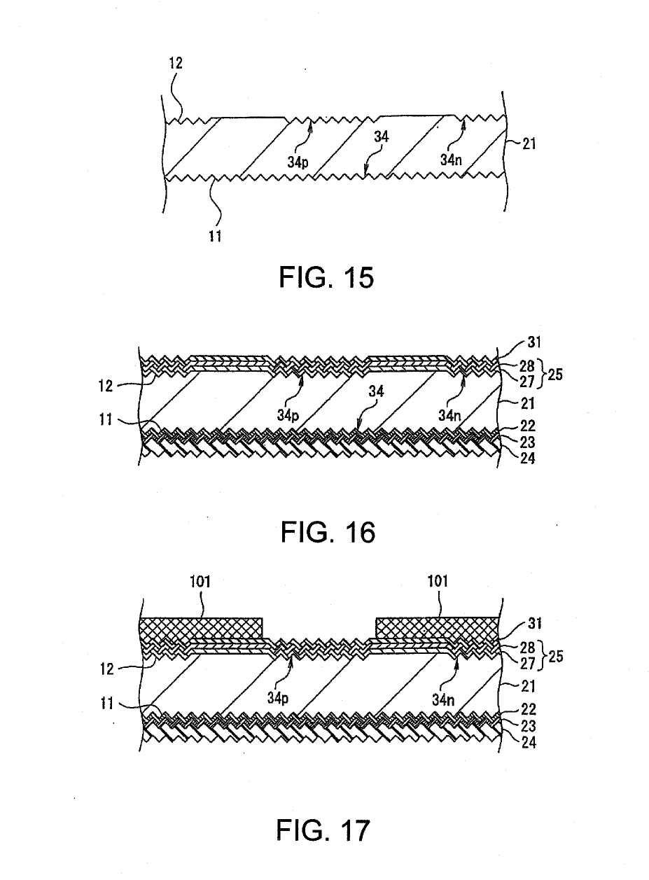

Subsequently, as shown in FIGS. 15 and 16, the resist film 100 is removed, and by means of a method such as PECVD or sputtering, the i-type amorphous silicon layer 22, the n-type amorphous silicon layer 23, and the protective layer 24 are sequentially laminated on the light receiving surface 11, while the i-type amorphous silicon layer 27, the n-type amorphous silicon layer 28, and the insulation layer 31 are sequentially laminated on the rear surface 12. As a result of this step, the IN layer 25 is laminated in the region where the textured structures 34n, 34p are formed. The unevenness of the textured structures 34n, 34p is reflected in the IN layer 25. Meanwhile, the portions of the IN layer 25 and insulation layer 31 laminated in the planar region that has been protected by the resist film 100 have planar surfaces.

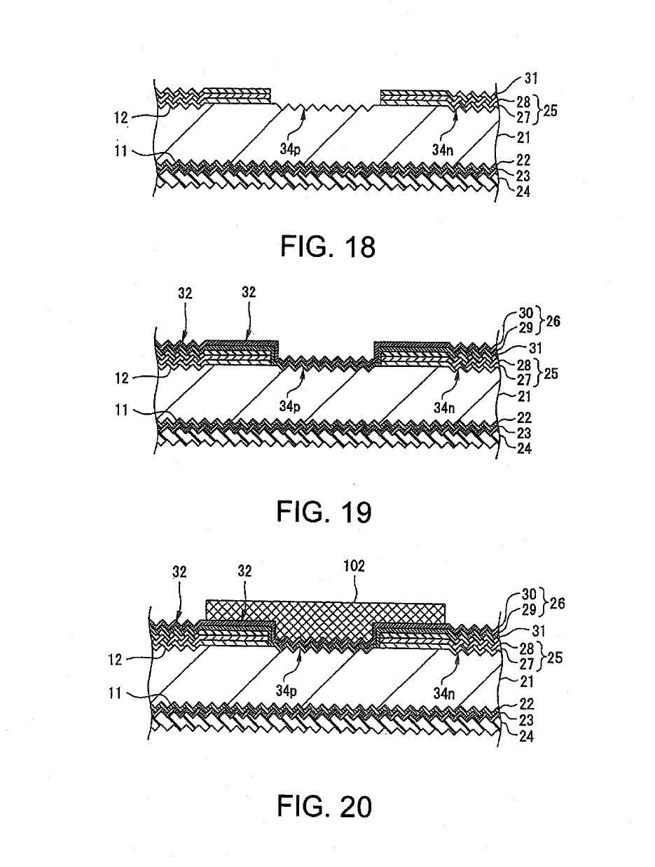

Subsequently, for example, as shown in FIGS. 17 and 18, a resist film 101 is used as a mask to pattern the respective layers laminated on the rear surface 12. First, the insulation layer 31 is partially etched and removed. The region where the insulation layer 31 is removed corresponds to the region of the rear surface 12 where the IP layer 26 is to be laminated in a later step. For example, after completing the etching of the insulation layer 31, the resist film 101 is removed, and then the exposed IN layer 25 is etched using the patterned insulation layer 31 as a mask. As a result of this step, a patterned IN layer 25 and insulation layer 31 are formed on the rear surface 12, and the region of the rear surface 12 having the textured structure 34p formed thereon becomes exposed.

Subsequently, as shown in FIG. 19, the IP layer 26 is laminated over the rear surface 12 in the entire area except for the edge region, for example. As a result of this step, the region where the textured structures 34n, 34p are formed is laminated with the IP layer 26. The unevenness of the textured structures 34n, 34p are reflected in the laminated IP layer 26. Meanwhile, the portion of the IP layer 26 laminated on the flat insulation layer 31 has a planar surface, and forms the planar overlap part 32. According to this step, an overlap part 32 having a planar surface and an overlap part 32 reflecting the unevenness of the textured structure 34n are created.

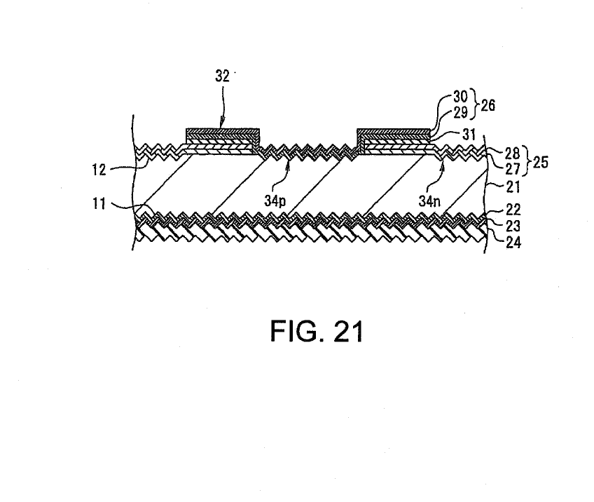

Subsequently, for example, as shown in FIGS. 20 and 21, a resist film 102 is used as a mask to partially etch and remove the IP layer 26 and insulation layer 31 laminated on the IN layer 25. The etched region is the region in which the unevenness of the textured structure 34n is reflected. In this step, the IP layer 26 is etched first, and then the patterned IP layer 26 is used as a mask to etch the insulation layer 31. As a result of this step, part of the IN layer 25 becomes exposed.

In the subsequent steps, the n-side electrode 40 and the p-side electrode 50 are formed as explained above with reference to FIGS. 10-12 in a manner such that the separation groove 60 will be located above the planar overlap part 32.

As described above, in the photoelectric converter 10, the textured structure is formed in at least part of the region of the rear surface 12 where the IN layer 25 and the IP layer 26 are laminated. According to this configuration, the contact area of at least one of the IN layer 25 and the IP layer 26 with respect to the corresponding electrodes is enlarged. As a result, contact resistance can be reduced, and carrier extraction efficiency can be enhanced. Meanwhile, no textured structure is formed in the region which receives thereon an electrode edge of the n-side electrode 40 and an electrode edge of the p-side electrode 50 that are located along the separation groove 60. Accordingly, the respective electrode edges along the separation groove 60 are formed on a planar surface. The separation groove 60 is located at a position corresponding to the etching edges during patterning of the electrodes. By configuring a planar region having no textured structure to serve as the etching edges, bleeding or smudging of the resist and the etching paste can be prevented, thereby enabling strict control of the line width. As a result, variances in electrode widths can be minimized, so that, for example, even when the separation groove 60 is made narrower and the electrode area is enlarged, insulation between the electrodes can be maintained favorably. Further, in the photoelectric converter 10, the textured structure 34p is preferably formed in at least the region where the IP layer 26 is to be laminated. With this configuration, the contact area between the IP layer 26 and the p-side electrode 50 is increased, and the area of p-n junction between the n-type monocrystalline silicon substrate 21 and the IP layer 26 is also increased. As a result of a cooperative effect of these increased areas, the photoelectric conversion efficiency can be enhanced in the photoelectric converter 10.

Design modifications can be made to the above-described embodiments without deviating from the objects of the present invention. For example, while the IP layer 26 is laminated after the IN layer 25 is laminated in the above embodiments, the IP layer 26 may be laminated first. In this case, for example, the insulation layer 31 is laminated on the IP layer 26. Further, in the region of the rear surface 12 where the IP layer 26 is to be laminated, the textured structure is not formed, while the textured structure 34n can be formed over the entire area of the rear surface 12 in which the IN layer 25 is to be laminated except for the region where the insulation layer 31 is to be laminated.

### LIST OF REFERENCE NUMERALS

10 photoelectric converter; 11 light receiving surface; 12 rear surface; 13 first conductive layer; 14 second conductive layer; 20 photoelectric conversion part; 21 n-type monocrystalline silicon substrate; 22, 27, 29 i-type amorphous silicon layer; 23, 28 n-type amorphous silicon layer; 24 protective layer; 25 IN amorphous silicon layer (IN layer); 26 IP amorphous silicon layer (IP layer); 30 p-type amorphous silicon layer; 31 insulation layer; 32 overlap part; 34, 34n, 34p textured structure; 40 n-side electrode; 41, 51 finger electrode part; 42,52 bus bar electrode part; 43, 53 first conductive layer; 44, 54 second conductive layer; 45, 55 third conductive layer; 46, 56 fourth conductive layer; 50 p-side electrode; 60 separation groove.

1. A photoelectric converter, comprising:
a semiconductor substrate;
a first amorphous semiconductor layer formed on a first surface of the semiconductor substrate and including a amorphous semiconductor layer of a first conduction type;
a second amorphous semiconductor layer formed on the first surface of the semiconductor substrate in a region where the first conduction type amorphous semiconductor layer is absent and including a amorphous semiconductor layer of a second conduction type;
a first electrode electrically connected to the first amorphous semiconductor layer; and
a second electrode separated from the first electrode by means of a separation groove and electrically connected to the second amorphous semiconductor layer,
wherein a textured structure is formed in at least part of a region of the first surface where the first amorphous semiconductor layer and the second amorphous semiconductor layer are formed directly contacting the first surface.

2. The photoelectric converter according to claim 1, wherein
within the region where the first amorphous semiconductor layer and the second amorphous semiconductor layer are formed directly contacting the semiconductor substrate, the textured structure is formed in at least part of said region excluding a region which receives thereon an electrode edge of the first electrode and an electrode edge of the second electrode that are located along the separation groove.

3. The photoelectric converter according to claim 1, wherein
a part of the first amorphous semiconductor layer is laminated over a part of the second amorphous semiconductor layer via an insulation layer, and
within a region where the first amorphous semiconductor layer is formed, the textured structure is formed in at least part of said region excluding a region where the insulation layer is formed.

4. The photoelectric converter according to claim 2, wherein
within the region where the first amorphous semiconductor layer is formed, the textured structure is formed over substantially an entire area excluding a region where the insulation layer is formed.

5. The photoelectric converter according to claim 1, wherein
the first amorphous semiconductor layer is a p-type amorphous semiconductor layer, and
the second amorphous semiconductor layer is an n-type amorphous semiconductor layer.

6. The photoelectric converter according to claim 2, wherein
the first amorphous semiconductor layer is a p-type amorphous semiconductor layer, and
the second amorphous semiconductor layer is an n-type amorphous semiconductor layer.

7. The photoelectric converter according to claim 3, wherein
the first amorphous semiconductor layer is a p-type amorphous semiconductor layer, and
the second amorphous semiconductor layer is an n-type amorphous semiconductor layer.

8. The photoelectric converter according to claim 4, wherein
the first amorphous semiconductor layer is a p-type amorphous semiconductor layer, and
the second amorphous semiconductor layer is an n-type amorphous semiconductor layer.

9. A method for producing a photoelectric converter, comprising:
a first step of laminating, on a first surface of a semiconductor substrate, a first amorphous semiconductor layer including a amorphous semiconductor layer of a first conduction type;
a second step of laminating, on the first surface of the semiconductor substrate in a region where the first conduction type amorphous semiconductor layer is absent, a second amorphous semiconductor layer including a amorphous semiconductor layer of a second conduction type; and
a step of forming a first electrode on the first amorphous semiconductor layer and also forming, on the second amorphous semiconductor layer, a second electrode separated from the first electrode by means of a separation groove,
the method further comprising a texture forming step of forming a textured structure on the first surface and a second surface of the semiconductor substrate while protecting at least a region of the first surface which eventually receives thereon an electrode edge of the first electrode and an electrode edge of the second electrode that are located along the separation groove.

10. The photoelectric converter producing method according to claim 9, wherein
a step of laminating an insulation layer on the first amorphous semiconductor layer is performed before the second step; and
in the texture forming step, the insulation layer is used as a mask to form the textured structure in a region of the first surface where the second amorphous semiconductor layer is to be laminated.
